(19) United States
(12) Patent Application Publication
(10) Pub. No.: US 2026/0155839 A1
(43) Pub. Date: Jun. 4, 2026

(54) ASYMMETRIC HARD READ CHANNEL ESTIMATION IN MEMORY DEVICES

(71) Applicant: SK hynix Inc., Icheon-si (KR)

(72) Inventors: Pengfei Huang, San Jose, CA (US); Fan Zhang, Fremont, CA (US)

(21) Appl. No.: 18/964,590

(22) Filed: Dec. 1, 2024

(51) Int. Cl. H03M 13/11; H03M 13/39

(52) U.S. Cl. CPC H03M 13/1177; H03M 13/3927

(57) ABSTRACT

Methods and systems for improving performance of a decoder in a memory device are described. An example method includes receiving a noisy codeword that is based on a transmitted codeword generated from a low-density parity-check (LDPC) code, and determining, based on the noisy codeword, a ones count and a checksum. The method further includes determining, based on the ones count and the checksum, an asymmetric ratio, a first log-likelihood ratio (LLR) value indicative of a bit being zero-valued, and a second LLR value indicative of the bit being one-valued. Then, the method includes generating an LLR sequence by applying the first LLR value and the second LLR value to each element of the noisy codeword, and performing a hard decoding operation on the LLR sequence to generate a candidate version of the transmitted codeword. An example system implements the above-described method using one or more processors.

### TECHNICAL FIELD

This patent document generally relates to memory devices with error-correcting codes, and more specifically, to improving the performance of low-density parity-check (LDPC) codes used in memory devices.

### BACKGROUND

Error-correcting code (ECC) memory is a type of computer data storage that can detect and correct the most common kinds of internal data corruption. ECC memory is primarily used in servers and workstations where data integrity is crucial. It works by adding extra bits to each data word, which are used to check and correct errors. This ensures that data read from memory is always accurate, even if a bit has been flipped due to electrical interference or other issues. ECC memory is essential for applications requiring high reliability and stability, such as financial systems, scientific computing, and mission-critical databases.

### SUMMARY

Embodiments of the disclosed technology relate to methods, systems, and devices that improve performance of a low-density parity check (LDPC) code in a memory device. In an example, the performance of the memory device is improved by estimating an asymmetric ratio and the associated log-likelihood ratios (LLRs) using the ones count and a partial checksum. The improved decoder is compatible with both encoder-randomizer-NAND (ERN) and randomizer-encoder-NAND (REN) architectures, and improves the quality-of-service (QoS) of the memory device. The disclosed embodiments provide significant benefits for high-density NAND flash memory, e.g., the quad-level cell (QLC) architecture for NAND flash memory.

In one example, a method for improving a performance of a decoder in a memory device is described. The method includes receiving a noisy codeword that is based on a transmitted codeword generated from an LDPC code, and determining, based on the noisy codeword, a ones count and a checksum. The method further includes determining, based on the ones count and the checksum, an asymmetric ratio, a first LLR value indicative of a bit being zero-valued, and a second LLR value indicative of the bit being one-valued. Then, the method includes generating an LLR sequence by applying the first LLR value and the second LLR value to each element of the noisy codeword, and performing a hard decoding operation on the LLR sequence to generate a candidate version of the transmitted codeword.

In another example, the methods may be embodied in the form of an apparatus that includes one or more processors and a memory coupled to the one or more processors.

In yet another example, the methods may be embodied in the form of processor-executable instructions and stored on a computer-readable program medium.

The subject matter described in this patent document can be implemented in specific ways that provide one or more of the following features.

### BRIEF DESCRIPTION OF THE DRAWINGS

FIG. 1 illustrates an example of a memory system.

FIG. 2 is an illustration of an example non-volatile memory device.

FIG. 3 is an example diagram illustrating the cell voltage level distribution (Vth) of a non-volatile memory device.

FIG. 4 is another example diagram illustrating the cell voltage level distribution (Vth) of a non-volatile memory device.

FIG. 5 is an example diagram illustrating the cell voltage level distribution (Vth) of a non-volatile memory device before and after program interference.

FIG. 6 is an example diagram illustrating the cell voltage level distribution (Vth) of a non-volatile memory device as a function of the reference voltage.

FIG. 7A shows an example of the randomizer-encoder-NAND (REN) architecture.

FIG. 7B shows an example of the encoder-randomizer-NAND (ERN) architecture.

FIG. 8 shows an example table for determining the asymmetric ratio and the LLR metrics based on the partial checksum and ones count.

FIG. 9 illustrates a flowchart of an example method for improving the performance of a memory device.

FIG. 10 is an example diagram illustrating a storage device that can be configured to implement the described embodiments.

### DETAILED DESCRIPTION

Semiconductor memory devices may be volatile or nonvolatile. The volatile semiconductor memory devices perform read and write operations at high speeds, while contents stored therein may be lost at power-off. The nonvolatile semiconductor memory devices may retain contents stored therein even at power-off. The nonvolatile semiconductor memory devices may be used to store contents, which must be retained regardless of whether they are powered.

With an increase in a need for a large-capacity memory device, a multi-level cell (MLC) or multi-bit memory device storing multi-bit data per cell is becoming more common. However, memory cells in an MLC non-volatile memory device must have threshold voltages corresponding to four or more discriminable data states in a limited voltage window. For improvement of data integrity in non-volatile memory devices, the levels, and distributions of read voltages for discriminating the data states must be adjusted over the lifetime of the memory device to have optimal values during read operations and/or read attempts.

Section headings are used in the present document to improve readability of the description and do not in any way limit the discussion or the embodiments (and/or implementations) to the respective sections only.

### 1 Introduction and Example Embodiments of the Disclosed Technology

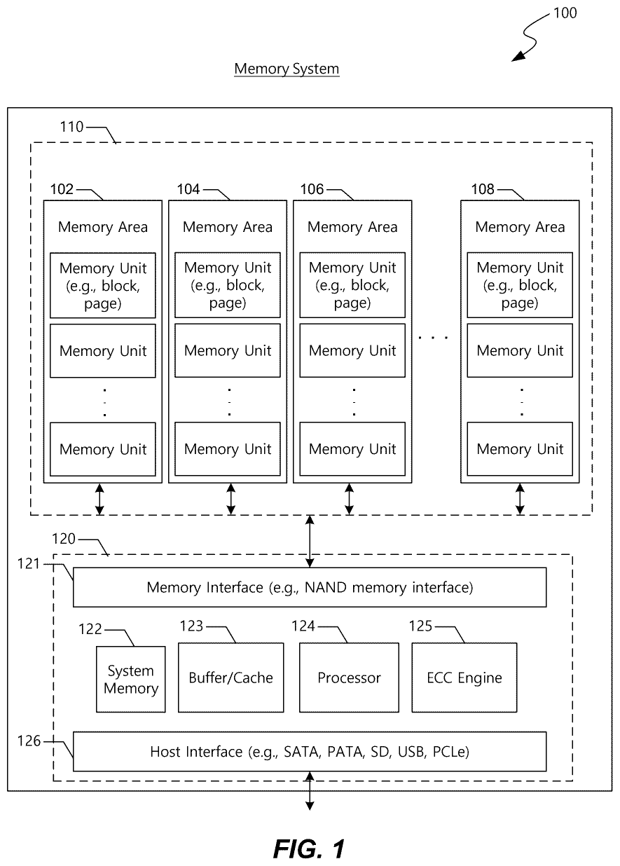

FIGS. 1-6 overview a non-volatile memory system (e.g., a flash-based memory, NAND flash) in which embodiments of the disclosed technology may be implemented.

FIG. 1 is a block diagram of an example of a memory system 100 implemented based on some embodiments of the disclosed technology. The memory system 100 includes a memory module 110 that can be used to store information for use by other electronic devices or systems. The memory system 100 can be incorporated (e.g., located on a circuit board) in other electronic devices and systems. Alternatively, the memory system 100 can be implemented as an external storage device such as a USB flash drive and a solid-state drive (SSD).

The memory module 110 included in the memory system 100 can include memory areas (e.g., memory arrays) 102, 104, 106, and 108. Each of the memory areas 102, 104, 106, and 108 can be included in a single memory die or in multiple memory dice. The memory die can be included in an integrated circuit (IC) chip.

Each of the memory areas 102, 104, 106, and 108 includes a plurality of memory cells. Read, program, or erase operations can be performed on a memory unit basis. Thus, each memory unit can include a predetermined number of memory cells. The memory cells in a memory area 102, 104, 106, and 108 can be included in a single memory die or in multiple memory dice.

The memory cells in each of memory areas 102, 104, 106, and 108 can be arranged in rows and columns in the memory units. Each of the memory units can be a physical unit. For example, a group of a plurality of memory cells can form a memory unit. Each of the memory units can also be a logical unit. For example, the memory unit can be a block or a page that can be identified by a unique address such as a block address or a page address, respectively. For another example, wherein the memory areas 102, 104, 106, and 108 can include computer memories that include memory banks as a logical unit of data storage, the memory unit can be a bank that can be identified by a bank address. During a read or write operation, the unique address associated with a particular memory unit can be used to access that particular memory unit. Based on the unique address, information can be written to or retrieved from one or more memory cells in that particular memory unit.

The memory cells in the memory areas 102, 104, 106, and 108 can include non-volatile memory cells. Examples of non-volatile memory cells include flash memory cells, phase change random-access memory (PRAM) cells, magneto-resistive random-access memory (MRAM) cells, or other types of non-volatile memory cells. In an example implementation where the memory cells are configured as NAND flash memory cells, the read or write operation can be performed on a page basis. However, an erase operation in a NAND flash memory is performed on a block basis.

Each of the non-volatile memory cells can be configured as a single-level cell (SLC) or multiple-level memory cell. A single-level cell can store one bit of information per cell. A multiple-level memory cell can store more than one bit of information per cell. For example, each of the memory cells in the memory areas 102, 104, 106, and 108 can be configured as a multi-level cell (MLC) to store two bits of information per cell, a triple-level cell (TLC) to store three bits of information per cell, or a quad-level cells (QLC) to store four bits of information per cell. In another example, each of the memory cells in memory area 102, 104, 106, and 108 can be configured to store at least one bit of information (e.g., one bit of information or multiple bits of information), and each of the memory cells in memory area 102, 104, 106, and 108 can be configured to store more than one bit of information.

As shown in FIG. 1, the memory system 100 includes a controller module 120. The controller module 120 includes a memory interface 121 to communicate with the memory module 110, a host interface 126 to communicate with a host (not shown), a processor 124 to execute firmware-level code, and caches and memories 123 and 122, respectively to temporarily or persistently store executable firmware/instructions and associated information. In some implementations, the controller unit 120 can include an error correction engine 125 to perform error correction operation on information stored in the memory module 110. Error correction engine 125 can be configured to detect/correct single bit error or multiple bit errors. In another implementation, error correction engine 125 can be located in the memory module 110.

The host can be a device or a system that includes one or more processors that operate to retrieve data from the memory system 100 or store or write data into the memory system 100. In some implementations, examples of the host can include a personal computer (PC), a portable digital device, a digital camera, a digital multimedia player, a television, and a wireless communication device.

In some implementations, the controller module 120 can also include a host interface 126 to communicate with the host. Host interface 126 can include components that comply with at least one of host interface specifications, including but not limited to, Serial Advanced Technology Attachment (SATA), Serial Attached Small Computer System Interface (SAS) specification, Peripheral Component Interconnect Express (PCIe).

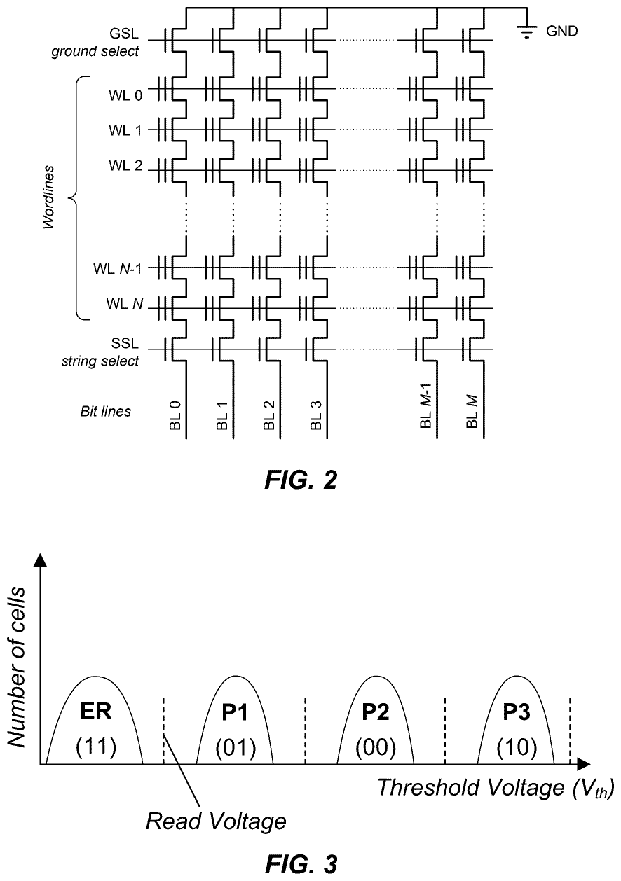

FIG. 2 illustrates an example of a memory cell array implemented based on some embodiments of the disclosed technology.

In some implementations, the memory cell array can include NAND flash memory array that is partitioned into many blocks, and each block contains a certain number of pages. Each block includes a plurality of memory cell strings, and each memory cell string includes a plurality of memory cells.

In some implementations where the memory cell array is NAND flash memory array, read and write (program) operations are performed on a page basis, and erase operations are performed on a block basis. All the memory cells within the same block must be erased at the same time before performing a program operation on any page included in the block. In an implementation, NAND flash memories may use an even/odd bit-line structure. In another implementation, NAND flash memories may use an all-bit-line structure. In the even/odd bit-line structure, even and odd bit-lines are interleaved along each word-line and are alternatively accessed so that each pair of even and odd bit-lines can share peripheral circuits such as page buffers. In all-bit-line structure, all the bit-lines are accessed at the same time.

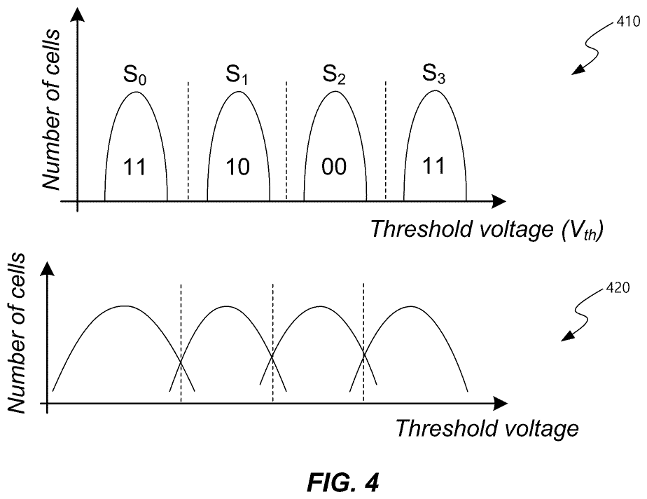

FIG. 3 illustrates an example of threshold voltage distribution curves in a multi-level cell device, wherein the number of cells for each program/erase state is plotted as a function of the threshold voltage. As illustrated therein, the threshold voltage distribution curves include the erase state (denoted “ER” and corresponding to “11”) with the lowest threshold voltage, and three program states (denoted “P1”, “P2” and “P3” corresponding to “01”, “00” and “10”, respectively) with read voltages in between the states (denoted by the dotted lines). In some embodiments, each of the threshold voltage distributions of program/erase states has a finite width because of differences in material properties across the memory array.

Although FIG. 3 shows a multi-level cell device by way of example, each of the memory cells can be configured to store any number of bits per cell. In some implementations, each of the memory cells can be configured as a single-level cell (SLC) to store one bit of information per cell, or as a triple-level cell (TLC) to store three bits of information per cell, or as a quad-level cells (QLC) to store four bits of information per cell.

In writing more than one data bit in a memory cell, fine placement of the threshold voltage levels of memory cells is needed because of the reduced distance between adjacent distributions. This is achieved by using incremental step pulse program (ISPP), i.e., memory cells on the same word-line are repeatedly programmed using a program-and-verify approach with a staircase program voltage applied to word-lines. Each programmed state associates with a verify voltage that is used in verify operations and sets the target position of each threshold voltage distribution window.

Read errors can be caused by distorted or overlapped threshold voltage distribution. An ideal memory cell threshold voltage distribution can be significantly distorted or overlapped due to, e.g., program and erase (P/E) cycle, cell-to-cell interference, and data retention errors, which will be discussed in the following, and such read errors may be managed in most situations by using error correction codes (ECCO).

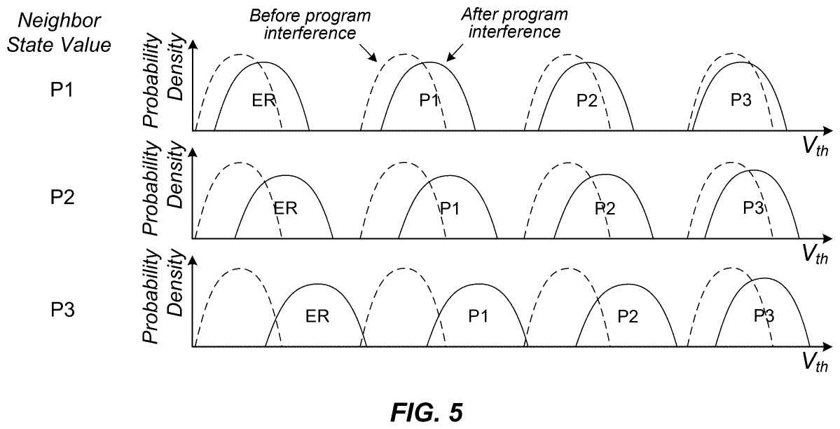

FIG. 4 illustrates an example of ideal threshold voltage distribution curves 410 and an example of distorted threshold voltage distribution curves 420. The vertical axis indicates the number of memory cells that has a particular threshold voltage represented on the horizontal axis.

For n-bit multi-level cell NAND flash memory, the threshold voltage of each cell can be programmed to 2ⁿ possible values. In an ideal multi-level cell NAND flash memory, each value corresponds to a non-overlapping threshold voltage window.

Flash memory P/E cycling causes damage to a tunnel oxide of floating gate of a charge trapping layer of cell transistors, which results in threshold voltage shift and thus gradually degrades memory device noise margin. As P/E cycles increase, the margin between neighboring distributions of different programmed states decreases and eventually the distributions start overlapping. The data bit stored in a memory cell with a threshold voltage programmed in the overlapping range of the neighboring distributions may be misjudged as a value other than the original targeted value.

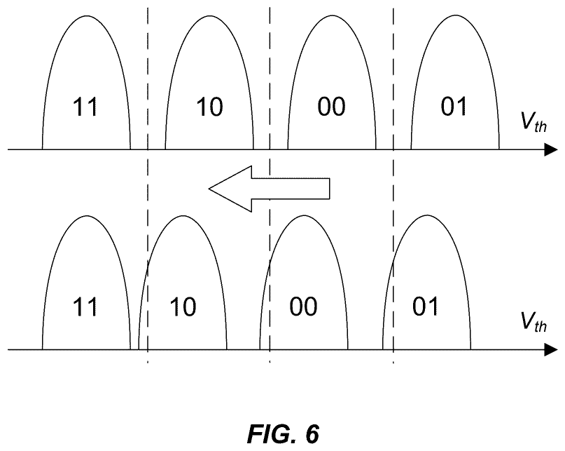

FIG. 5 illustrates an example of a cell-to-cell interference in NAND flash memory. The cell-to-cell interference can also cause threshold voltages of flash cells to be distorted. The threshold voltage shift of one memory cell transistor can influence the threshold voltage of its adjacent memory cell transistor through parasitic capacitance-coupling effect between the interfering cell and the victim cell. The amount of the cell-to-cell interference may be affected by NAND flash memory bit-line structure. In the even/odd bit-line structure, memory cells on one word-line are alternatively connected to even and odd bit-lines and even cells are programmed ahead of odd cells in the same word-line. Therefore, even cells and odd cells experience different amount of cell-to-cell interference. Cells in all-bit-line structure suffer less cell-to-cell interference than even cells in the even/odd bit-line structure, and the all-bit-line structure can effectively support high-speed current sensing to improve the memory read and verify speed.

The dotted lines in FIG. 5 denote the nominal distributions of P/E states (before program interference) of the cells under consideration, and the “neighbor state value” denotes the value that the neighboring state has been programmed to. As illustrated in FIG. 5, if the neighboring state is programmed to P1, the threshold voltage distributions of the cells under consideration shift by a specific amount. However, if the neighboring state is programmed to P2, which has a higher threshold voltage than P1, that results in a greater shift compared to the neighboring state being P1. Similarly, the shift in the threshold voltage distributions is greatest when the neighboring state is programmed to P3.

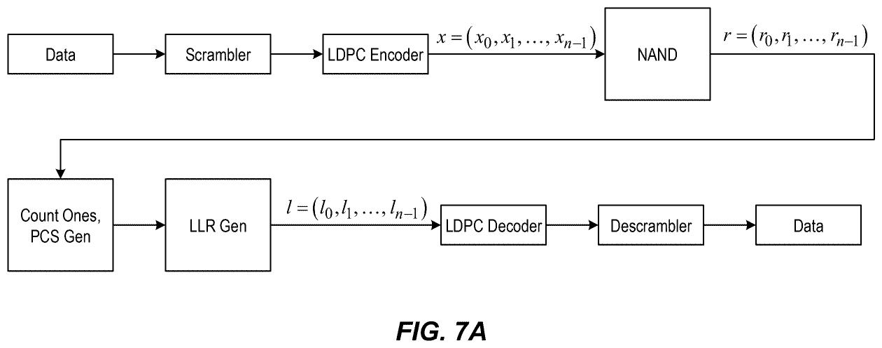

FIG. 6 illustrates an example of a retention error in NAND flash memory by comparing normal threshold-voltage distribution and shifted threshold-voltage distribution. The data stored in NAND flash memories tend to get corrupted over time and this is known as a data retention error. Retention errors are caused by loss of charge stored in the floating gate or charge trap layer of the cell transistor. Due to wear of the floating gate or charge trap layer, memory cells with more program erase cycles are more likely to experience retention errors. In the example of FIG. 6, comparing the top row of voltage distributions (before corruption) and the bottom row of distributions (contaminated by retention error) reveals a shift to the left.

In the NAND flash memory examples described above, a “hard read” is an operation to determine hard information such as by comparing the threshold voltage of a memory cell, e.g., flash memory cell, to reference voltages delineating ranges of voltages corresponding to particular states. A hard read can be full-confidence sensing, e.g., sensing that does not involve other information about the digits of the data value such as confidence. That is, the data value sensed from the memory cell is assumed to be the data value that was programmed to the memory. For full-confidence sensing, a digit of a data value that is sensed, e.g., read from memory, as a “0” will have a corresponding LLR of +1, and a data value that is sensed as a “1” can have a corresponding LLR of −1.

Furthermore, the example NAND-based storage systems discussed above use low-density parity check (LDPC) codes, which are a type of error-correcting code used to ensure data integrity in non-volatile memory (NVM) devices, such as flash memory. The encoding process begins by dividing the original data into blocks of a fixed size. A sparse parity-check matrix is then used to generate parity bits, which are combined with the data bits to form a codeword. This codeword is stored in the non-volatile memory, which retains data even when power is lost.

When data is read from the non-volatile memory, it may contain errors due to various factors like wear and tear of the memory cells or environmental conditions. LDPC codes detect and correct these errors through a process that involves calculating a syndrome by multiplying the read codeword by the transpose of the parity-check matrix (typically denoted H). If the syndrome is non-zero, it indicates the presence of errors. An iterative decoding algorithm (e.g., the belief propagation algorithm) is then used to correct the errors. This algorithm iteratively updates probabilities of each bit being 0 or 1 by passing messages between variable nodes and check nodes in a bipartite graph until the probabilities converge to stable values, resulting in the corrected codeword and the extraction of the original data.

In NAND-based storage systems (e.g., the examples illustrated in FIGS. 1-6) and solid-state drive (SSD) applications, the fail bit count (FBC) of the first read is usually asymmetric, i.e., the number of 1-to-0 errors (N_{1→0}) is not equal to the number of 0-to-1 errors (N_{0→1}). Herein, the asymmetry ratio α is defined as the number of 1-to-0 errors divided by the FBC, i.e., α=N_{1→0}/FBC. Furthermore, it is very likely that the first read has a very high asymmetry ratio, e.g., 0.9. This asymmetry information can be utilized to improve the correction capability of a min-sum hard (MSH) decoder or a bit-flipping (BF) decoder, thereby enhancing the success rate of first read as well as the associated quality-of-service (QoS) of the NAND-based storage systems and SSD applications.

Embodiments of the disclosed technology provide methods and systems directed to estimating the asymmetry ratio and the related log-likelihood ratio (LLR) using the ones count and a partial checksum as inputs. In particular, two scenarios are considered: (1) the average ones count of a codeword is known, and (2) the exact ones count of the codeword is known. Furthermore, the described embodiments are flexible enough to be implementable in both encoder-randomizer-NAND (ERN) and randomizer-encoder-NAND (REN) architectures, and are therefore application to a wide range of SSD products. In some examples, the disclosed embodiments advantageously improve the QoS of enterprise SSD products significantly, and in particularly, the quad-level cell (QLC)-based high capacity SSDs.

In some embodiments, and for an LDPC code with m×n parity-check matrix H, the checksum (CS) computation of a length-n noisy codeword r is determined by first computing:

$$SYND = {rH}^{T} .$$

Herein, the T subscript represents the transpose operation, and the checksum (CS) is the number of ones in SYND. In other embodiments, for an LDPC code with m×n parity-check matrix H which has a sub-matrix Hₛ, the partial checksum (PCS) computation of a length-n noisy codeword r can be determined by first computing SYND=rHₛ^{T}, with the PCS being the number of ones in the vector SYND. In some examples, the sub-matrix is the circulant matrix associated with one or more check nodes of the bipartite graph of the LDPC code.

In these embodiments, the LLRs of the hard read channel are determined as:

$$LLR ( 1 ) = log ( \frac{p ( y = 1 \vert x = 0 )}{p ( y = 1 \vert x = 1 )} )$$

$$LLR ( 0 ) = log ( \frac{p ( y = 0 \vert x = 0 )}{p ( y = 0 \vert x = 1 )} )$$

### 2 Examples of REN Architecture Embodiments

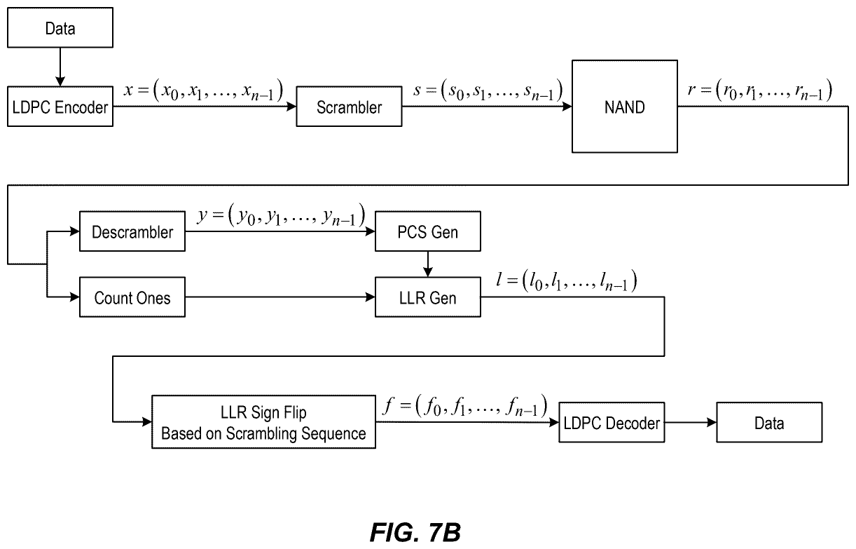

In some embodiments, determining the asymmetric ratio and LLR metrics based on the ones count and the (partial) checksum is implemented for the randomizer-encoder-NAND (REN) architecture, shown in FIG. 7A. As shown therein, the input data is scrambled prior to being encoded using the LDPC encoder, and then sent to the NAND. Two cases are considered:

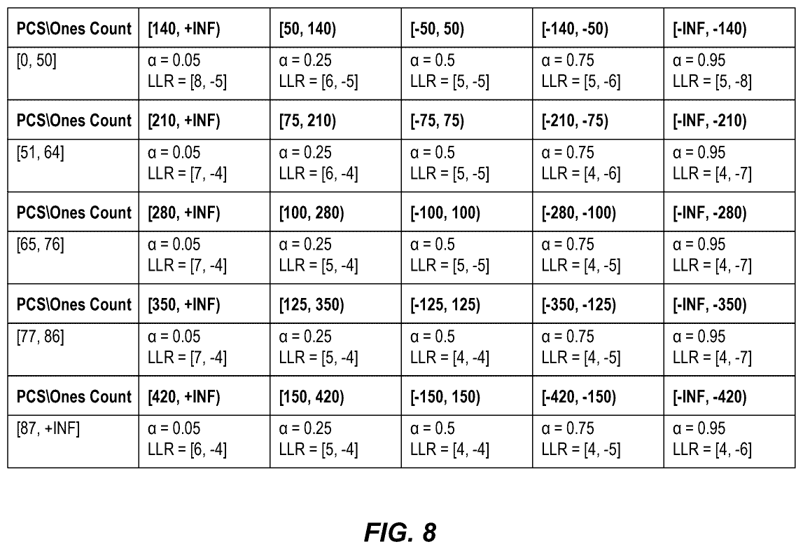

Case 1: Average ones count of a codeword is known. Here, the bits being scrambled supports the average ones count of a codeword x=(x₀, x₁, . . . , xₙ₋₁) being half of the codeword length, denoted n/2. The decoding procedure in an MSH LDPC decoder is as follows:
Step 1: Read raw data, r=(r₀, r₁, . . . , rₙ₋₁), from NAND
Step 2: Calculate the ones count, m(r), of the raw data (r₀, r₁, . . . , rₙ₋₁)
Step 3: Generate a partial checksum, PCS, of the raw data (r₀, r₁, . . . , rₙ₋₁)
Step 4: Use (m(r)−n/2) and PCS to index into a table (e.g., the table shown in FIG. 8) to determine the asymmetry ratio α and associated LLRs, e.g., LLR0_{(α)} and LLR1_{(α)}.
Step 5: If |α−0.5|>τ, a predetermined threshold (e.g., 0.4), then LLR0_{(α)} and LLR1_{(α)} are used as the optimal LLRs (LLR0₍ₒₚₜ₎ and LLR1₍ₒₚₜ₎); otherwise, the optimal LLRs are set to default values (LLR0_{(def)} and LLR1_{(def)}), e.g., LLR0_{(def)}=4 and LLR1_{(def)}=−4.
Step 6: Generate an LLR sequence l=(l₀, l₁, . . . , lₙ₋₁) by applying LLR0₍ₒₚₜ₎ and LLR1₍ₒₚₜ₎ to the raw data (r₀, r₁, . . . , rₙ₋₁)
Step 7: Perform MSH decoding with the LLR sequence l=(l₀, l₁, . . . , lₙ₋₁)

In a numerical example, and assuming that n=36864, τ=0.4 and (LLR0_{(def)}=4, LLR1_{(def)}=−4), the decoding procedure described above is applied as follows:
Step 1: Receive r=[0,1,0,1,1,1 . . . 1,0,1,1]
Step 2: Compute m(r)=18132
Step 3: Compute PCS=72
Step 4: Use (m(r)−n/2)=18132−18432=−300 and PCS=72 to index into the table shown in FIG. 8, and determine α=0.95, LLR0_{(α)}=4 and LLR1_{(α)}=−7
Step 5: Since |0.95−0.5|=0.45>0.4, LLR0₍ₒₚₜ₎=4 and LLR1₍ₒₚₜ₎=−7
Step 6: Generate l=[4,−7,4,−7,−7,−7 . . . −7,4,−7,−7]
Step 7: Perform MSH decoding with l=[4,−7,4,−7,−7,−7 . . . −7,4,−7,−7]

Case 2: Exact ones count of a codeword is known. Here, the exact ones count m(x) of a codeword x=(x₀, x₁, . . . , xₙ₋₁) is known at the LDPC decoder. In some examples, the corresponding encoder is configured to store m(x) in the punctured information bits of the codeword. The decoding procedure in an iterative MSH LDPC decoder is as follows:
Step 1: Read raw data, r=(r₀, r₁, . . . , rₙ₋₁), from NAND
Step 2: Calculate the ones count, m(r), of the raw data (r₀, r₁, . . . , rₙ₋₁)
Step 3: Generate a partial checksum, PCS, of the raw data (r₀, r₁, . . . , rₙ₋₁)
Step 4: Perform a few iterations of the MSH decoder with default LLR values (e.g., LLR0_{(def)}=4, LLR1_{(def)}=−4) to determine m(x). In some examples, performing a few iterations of the MSH decoder includes performing 5% to 20% of the maximum number of iterations configured for the MSH decoder.
Step 5: Use (m(r)−m(x)) and PCS to index into a table (e.g., the table shown in FIG. 8) to determine the asymmetry ratio α and associated LLRs, e.g., LLR0_{(α)} and LLR1_{(α)}.
Step 6: Generate an LLR sequence l=(l₀, l₁, . . . , lₙ₋₁) by applying LLR0_{(α)} and LLR1_{(α)} to the raw data (r₀, r₁, . . . , rₙ₋₁)
Step 7: Perform the remaining number of iterations of the MSH decoder with the LLR sequence l=(l₀, l₁, . . . , lₙ₋₁). In some examples, performing the remaining number of iterations of the MSH decoder includes performing 80% to 95% of the maximum number of iterations configured for the MSH decoder.

In some embodiments, the exact ones count of a codeword, m(x), is not stored in the punctured information bits of the codeword that is received at the decoder, but in a spare single-layer cell (SLC) or a static random-access memory (SRAM) area, which is accessible to the decoder (albeit with a higher cost, e.g., greater latency). In these embodiments (and more generally, in embodiments where the decoder has access to the exact ones count without it being stored in the received codeword), Step 4 is omitted and the few iterations of the MSH decoder are not performed. Instead, all the iterations of the MSH decoder are performed in Step 7.

In the two cases considered above for the REN architecture, using PCS (the partial checksum) can be replaced by using the checksum itself. In some embodiments

In some embodiments, the ones count (e.g., m(x) or m(r)) is determined over the entire codeword, e.g., m(x) is the ones count of (x₀, x₁, . . . xₙ₋₁). In other embodiments, the ones count is determined over the first k<n bits of the codeword, e.g., m(r) is the ones count of (r₀, r₁, . . . , rₖ₋₁). In some examples, the first k bits correspond to the payload portion.

Furthermore, numerical simulations have evinced that for LDPC codes typically used in SSD applications and α=0.9, the described REN architecture can correct 50 more bits than a default LDPC decoder that does not incorporate the described embodiments.

### 3 Examples of ERN Architecture Embodiments

In some embodiments, determining the asymmetric ratio and LLR metrics based on the ones count and the (partial) checksum is implemented for the encoder-randomizer-NAND (ERN) architecture, shown in FIG. 7B. As shown therein, the input data is encoded by the LDPC encoder prior to being scrambled, and then sent to the NAND. Two cases are considered:

Case 1: Average ones count of a codeword is known. Here, the bits being scrambled supports the average ones count of a codeword x=(x₀, x₁, . . . , xₙ₋₁) being half of the codeword length, denoted n/2. Furthermore, the scrambling sequence is denoted c=(c₀, c₁, . . . , cₙ₋₁), and the output of the scrambler is denoted s=Bitwise_XOR(x, c). The decoding procedure in an MSH LDPC decoder is as follows:
Step 1: Read raw data, r=(r₀, r₁, . . . , rₙ₋₁), from NAND
Step 2: Calculate the ones count, m(r), of the raw data (r₀, r₁, . . . , rₙ₋₁)
Step 3: Descramble the raw data (r₀, r₁, . . . , rₙ₋₁) to obtain y=(y₀, y₁, . . . , yₙ₋₁)
Step 4: Generate a partial checksum, PCS, of y=(y₀, y₁, . . . , yₙ₋₁)
Step 5: Use (m(r)−n/2) and PCS to index into a table (e.g., the table shown in FIG. 8) to determine the asymmetry ratio α and associated LLRs, e.g., LLR0_{(α)} and LLR1_{(α)}.
Step 6: If |α−0.5|>τ, a predetermined threshold (e.g., 0.4), then LLR0_{(α)} and LLR1_{(α)} are used as the optimal LLRs (LLR0₍ₒₚₜ₎ and LLR1₍ₒₚₜ₎); otherwise, the optimal LLRs are set to default values (LLR0_{(def)} and LLR1_{(def)}, e.g., LLR0_{(def)}=4 and LLR1_{(def)}=−4.
Step 7: Generate an LLR sequence l=(l₀, l₁, . . . , lₙ₋₁) by applying LLR0₍ₒₚₜ₎ and LLR1₍ₒₚₜ₎ to the raw data (r₀, r₁, . . . , rₙ₋₁)
Step 8: Generate a flipped LLR sequence f=(f₀, f₁, . . . , fₙ₋₁) as follows:

```
FOR i = 0 : (n−1)
  IF scrambling sequence bit cᵢ == 1, THEN fᵢ = −lᵢ
    ELSE fᵢ = lᵢ
  END
END
```

Step 9: Perform MSH decoding with the LLR sequence f=(f₀, f₁, . . . , fₙ₋₁)

In a numerical example, and assuming that n=36864, τ=0.4, (LLR0_{(def)}=4, LLR1_{(def)}=−4) and the scrambling sequence is c=[0,0,1,1,0,0 . . . 0,1,0,0], the decoding procedure described above is applied as follows:
Step 1: Receive r=[0,1,0,1,1,1 . . . 1,0,1,1]
Step 2: Compute m(r)=18132
Step 3: Descramble to generate y=[0,1,1,0,1,1 . . . 1,1,1,1]
Step 4: Compute PCS=72
Step 5: Use (m(r)−n/2)=18132−18432=−300 and PCS=72 to index into the table shown in FIG. 8, and determine α=0.95, LLR0_{(α)}=4 and LLR1_{(α)}=−7
Step 6: Since |0.95−0.5|=0.45>0.4, LLR0₍ₒₚₜ₎=4 and LLR1₍ₒₚₜ₎=−7
Step 7: Generate l=[4,−7,4,−7,−7,−7 . . . −7,4,−7,−7]
Step 8: Generate f=[4,−7,−4,7,−7,−7 . . . −7,−4,−7,−7]
Step 9: Perform MSH decoding on f=[4,−7,−4,7,−7,−7 . . . −7,−4,−7,−7]

Case 2: Exact ones count of a codeword is known. Here, the exact ones count m(s) of the scrambled codeword s=(s₀, s₁, . . . , sₙ₋₁) is known at the LDPC decoder. In some examples, the corresponding encoder is configured to store m(s) in the punctured information bits of the codeword. The decoding procedure in an iterative MSH LDPC decoder is as follows:
Step 1: Read raw data, r=(r₀, r₁, . . . , rₙ₋₁), from NAND
Step 2: Calculate the ones count, m(r), of the raw data (r₀, r₁, . . . , rₙ₋₁)
Step 3: Descramble the raw data (r₀, r₁, . . . , rₙ₋₁) to obtain y=(y₀, y₁, . . . , yₙ₋₁)
Step 4: Generate a partial checksum, PCS, of y=(y₀, y₁, . . . , yₙ₋₁)
Step 5: Perform a few iterations of the MSH decoder with default LLR values (e.g., LLR0_{(def)}=4, LLR1_{(def)}=−4) to determine m(s). In some examples, performing a few iterations of the MSH decoder includes performing 5% to 20% of the maximum number of iterations configured for the MSH decoder.
Step 6: Use (m(r)−m(s)) and PCS to index into a table (e.g., the table shown in FIG. 8) to determine the asymmetry ratio α and associated LLRs, e.g., LLR0_{(α)} and LLR1_{(α)}.
Step 7: Generate an LLR sequence l=(l₀, l₁, . . . , lₙ₋₁) by applying LLR0_{(α)} and LLR1_{(α)} to the raw data (r₀, r₁, . . . , rₙ₋₁)
Step 8: Generate a flipped LLR sequence f=(f₀, f₁, . . . , fₙ₋₁) as follows:

```
FOR i = 0 : (n−1)
  IF scrambling sequence bit cᵢ == 1, THEN fᵢ = −lᵢ
    ELSE fᵢ = lᵢ
  END
END
```

Step 9: Perform the remaining number of iterations of the MSH decoder with the LLR sequence f=(f₀, f₁, . . . , fₙ₋₁). In some examples, performing the remaining number of iterations of the MSH decoder includes performing 80% to 95% of the maximum number of iterations configured for the MSH decoder.

In some embodiments, the exact ones count of a codeword, m(s), is not stored in the punctured information bits of the codeword that is received at the decoder, but in a spare single-layer cell (SLC) or a static random-access memory (SRAM) area, which is accessible to the decoder (albeit with a higher cost, e.g., greater latency). In these embodiments (and more generally, in embodiments where the decoder has access to the exact ones count without it being stored in the received codeword), Step 5 is omitted and the few iterations of the MSH decoder are not performed. Instead, all the iterations of the MSH decoder are performed in Step 9.

In the two cases considered above for the ERN architecture, using PCS (the partial checksum) can be replaced by using the checksum itself.

In some embodiments, the ones count (e.g., m(x), m(s) or m(r)) is determined over the entire codeword, e.g., m(x) is the ones count of (x₀, x₁, . . . xₙ₋₁). In other embodiments, the ones count is determined over the first k<n bits of the codeword, e.g., m(r) is the ones count of (r₀, r₁, . . . , rₖ₋₁). In some examples, the first k bits correspond to the payload portion.

Furthermore, numerical simulations have evinced that for LDPC codes typically used in SSD applications and α=0.9, the described ERN architecture can correct 50 more bits than a default decoder.

### 4 Additional Embodiments of the Disclosed Technology

Embodiments of the disclosed technology, as described and discussed above, use the ones count and the partial checksum (or checksum) to estimate the asymmetry ratio and the LLR metrics for a hard read channel. Herein, the calculation of the ones count and the LLR metrics is very simple. Furthermore, the described embodiments are applicable to both encoder-randomizer-NAND (ERN) and randomizer-encoder-NAND (REN) architectures. The estimated LLR metrics significantly improve the min-sum hard (MSH) decoding capability of the ECC decoder and reduce its latency, thereby enhancing the QoS of the memory device and/or SSD.

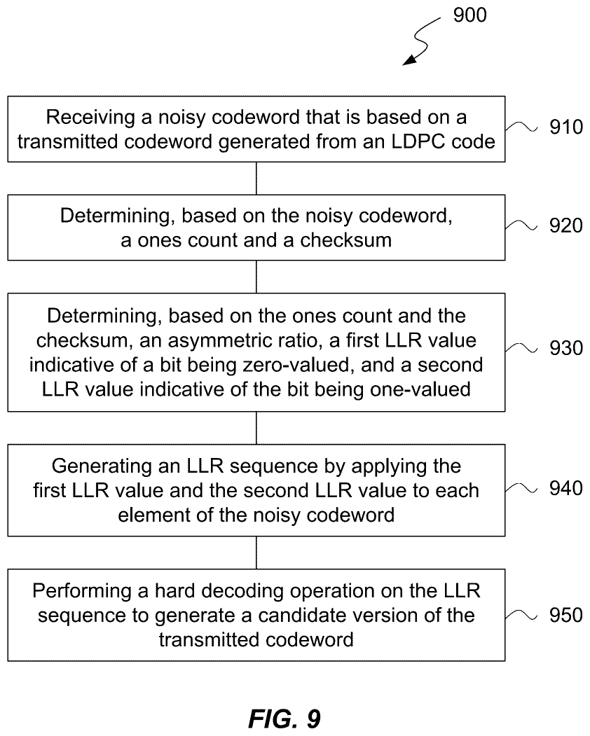

FIG. 9 illustrates a flowchart of an example method 900 for improving the performance of a memory device. The method 900 includes, at operation 910, receiving a noisy codeword that is based on a transmitted codeword generated from an LDPC code.

The method 900 includes, at operation 920, determining, based on the noisy codeword, a ones count and a checksum.

The method 900 includes, at operation 930, determining, based on the ones count and the checksum, an asymmetric ratio, a first LLR value indicative of a bit being zero-valued, and a second LLR value indicative of the bit being one-valued.

The method 900 includes, at operation 940, generating an LLR sequence by applying the first LLR value and the second LLR value to each element of the noisy codeword.

The method 900 includes, at operation 950, performing a hard decoding operation on the LLR sequence to generate a candidate version of the transmitted codeword.

In some embodiments, determining the checksum comprises determining a syndrome of the noisy codeword, e.g., by computing SYND=rH^{T}.

In some embodiments, determining the checksum comprises determining a partial checksum based a product of the noisy codeword and a submatrix of a parity-check matrix of the LDPC code, e.g., by computing SYND=rHₛ^{T}.

In some embodiments, determining the asymmetric ratio comprises determining a difference between (a) the ones count of the noisy codeword and (b) a length of the transmitted codeword divided by two, e.g., as described in Case 1 for both the REN and ERN architectures.

In some embodiments, determining the asymmetric ratio comprises determining a difference between (a) the ones count of the noisy codeword and (b) a ones count of the transmitted codeword, e.g., as described in Case 2 for both the ERN and REN architectures. In some examples, the ones count of the transmitted codeword is stored in one or more punctured information bits of the transmitted codeword. Herein, the ones count of the transmitted codeword is determined at the decoder by running a few iterations to extract the value from the one or more punctured information bits of the transmitted codeword.

In some embodiments, the transmitted codeword is generated by LDPC encoding a scrambled data sequence, e.g., in the REN architecture shown in FIG. 7A.

In some embodiments, the transmitted codeword is generated by scrambling an LDPC encoded data sequence, e.g., in the ERN architecture shown in FIG. 7B.

In some embodiments, determining the first LLR value and the second LLR value comprises retrieving the first LLR value and the second LLR value from a lookup table by using the ones count and the checksum to index into the lookup table.

In some embodiments, the memory device comprises a quad-level cell (QLC).

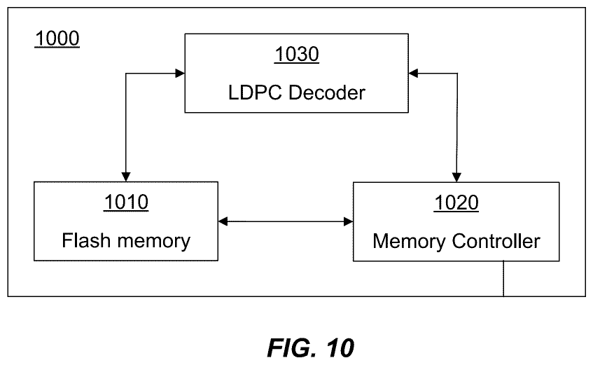

FIG. 10 is an example diagram illustrating a storage device that can be configured to implement the described embodiments. Referring to FIG. 10, a data storage device 1000 may include a flash memory 1010, a memory controller 1020, and an LDPC decoder 1030. The memory controller 1020 may control the flash memory 1010 and the LDPC decoder 1030 in response to control signals input from the outside of the data storage device 1000. In the data storage device 1000, the flash memory 1010 may be configured the same or substantially the same as a nonvolatile memory device. That is, the flash memory 1010 may read data from selected memory cells using different read voltages to output it to the memory controller 1020.

In some embodiments, the data storage device 1000 may be a memory card device, an SSD device, a multimedia card device, an SD card, a memory stick device, an HDD device, a hybrid drive device, or an USB flash device. For example, the data storage device 1000 may be a card which satisfies the standard for user devices such as a digital camera, a personal computer, and so on.

Implementations of the subject matter and the functional operations described in this patent document can be implemented in various systems, digital electronic circuitry, or in computer software, firmware, or hardware, including the structures disclosed in this specification and their structural equivalents, or in combinations of one or more of them. Implementations of the subject matter described in this specification can be implemented as one or more computer program products, i.e., one or more modules of computer program instructions encoded on a tangible and non-transitory computer readable medium for execution by, or to control the operation of, data processing apparatus. The computer readable medium can be a machine-readable storage device, a machine-readable storage substrate, a memory device, a composition of matter effecting a machine-readable propagated signal, or a combination of one or more of them. The term “data processing unit” or “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. Processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, flash memory devices. The processor and the memory can be supplemented by, or incorporated in, special purpose logic circuitry.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described and other implementations, enhancements and variations can be made based on what is described and illustrated in this patent document.

What is claimed is:

1. A method for improving a performance of a decoder in a memory device, comprising:
receiving a noisy codeword that is based on a transmitted codeword generated from a low-density parity-check (LDPC) code;
determining, based on the noisy codeword, a ones count and a checksum;
determining, based on the ones count and the checksum, an asymmetric ratio, a first log-likelihood ratio (LLR) value indicative of a bit being zero-valued, and a second LLR value indicative of the bit being one-valued;
generating an LLR sequence by applying the first LLR value and the second LLR value to each element of the noisy codeword; and
performing a hard decoding operation on the LLR sequence to generate a candidate version of the transmitted codeword.

2. The method of claim 1, wherein determining the checksum comprises:
determining a syndrome of the noisy codeword.

3. The method of claim 1, wherein determining the checksum comprises:
determining a partial checksum based a product of the noisy codeword and a submatrix of a parity-check matrix of the LDPC code.

4. The method of claim 1, wherein determining the asymmetric ratio comprises:
determining a difference between (a) the ones count of the noisy codeword and (b) a length of the transmitted codeword divided by two.

5. The method of claim 1, wherein determining the asymmetric ratio comprises:
determining a difference between (a) the ones count of the noisy codeword and (b) a ones count of the transmitted codeword.

6. The method of claim 5, wherein the ones count of the transmitted codeword is stored in one or more punctured information bits of the transmitted codeword.

7. The method of claim 1, wherein the transmitted codeword is generated by LDPC encoding a scrambled data sequence.

8. The method of claim 1, wherein the transmitted codeword is generated by scrambling an LDPC encoded data sequence.

9. The method of claim 1, wherein determining the first LLR value and the second LLR value comprises:
retrieving the first LLR value and the second LLR value from a lookup table by using the ones count and the checksum to index into the lookup table.

10. The method of claim 1, wherein the memory device comprises a quad-level cell (QLC).

11. A system for improving a performance of a decoder in a memory device, comprising:
one or more processors and a memory including instructions stored thereupon, wherein the instructions upon execution by the one or more processors cause the one or more processors to:
receive a noisy codeword that is based on a transmitted codeword generated from a low-density parity-check (LDPC) code;
determine, based on the noisy codeword, a ones count and a checksum;
determine, based on the ones count and the checksum, an asymmetric ratio, a first log-likelihood ratio (LLR) value indicative of a bit being zero-valued, and a second LLR value indicative of the bit being one-valued;
generate an LLR sequence by applying the first LLR value and the second LLR value to each element of the noisy codeword; and
perform a hard decoding operation on the LLR sequence to generate a candidate version of the transmitted codeword.

12. The system of claim 11, wherein the one or more processors are caused, as part of determining the checksum, to:
determine a syndrome of the noisy codeword, or
determine a partial checksum based a product of the noisy codeword and a submatrix of a parity-check matrix of the LDPC code.

13. The system of claim 11, wherein the one or more processors are caused, as part of determining the asymmetric ratio, to:
determine a difference between (a) the ones count of the noisy codeword and (b) either (i) a length of the transmitted codeword divided by two or (ii) a ones count of the transmitted codeword.

14. The system of claim 11, wherein the transmitted codeword is generated by LDPC encoding a scrambled data sequence.

15. The system of claim 11, wherein the transmitted codeword is generated by scrambling an LDPC encoded data sequence.

16. A non-transitory computer-readable storage medium having instructions stored thereupon for improving a performance of a decoder in a memory device, comprising:
instructions for receiving a noisy codeword that is based on a transmitted codeword generated from a low-density parity-check (LDPC) code;
instructions for determining, based on the noisy codeword, a ones count and a checksum;
instructions for determining, based on the ones count and the checksum, an asymmetric ratio, a first log-likelihood ratio (LLR) value indicative of a bit being zero-valued, and a second LLR value indicative of the bit being one-valued;
instructions for generating an LLR sequence by applying the first LLR value and the second LLR value to each element of the noisy codeword; and
instructions for performing a hard decoding operation on the LLR sequence to generate a candidate version of the transmitted codeword.

17. The non-transitory computer-readable storage medium of claim 16, wherein the instructions for determining the checksum comprise:
instructions for determining a syndrome of the noisy codeword, or
instructions for determining a partial checksum based a product of the noisy codeword and a submatrix of a parity-check matrix of the LDPC code.

18. The non-transitory computer-readable storage medium of claim 16, wherein the instructions for determining the asymmetric ratio comprise:
instructions for determining a difference between (a) the ones count of the noisy codeword and (b) either (i) a length of the transmitted codeword divided by two or (ii) a ones count of the transmitted codeword.

19. The non-transitory computer-readable storage medium of claim 16, wherein the transmitted codeword is generated by LDPC encoding a scrambled data sequence.

20. The non-transitory computer-readable storage medium of claim 16, wherein the transmitted codeword is generated by scrambling an LDPC encoded data sequence.
